(19) United States
(12) Patent Application Publication
(10) Pub. No.: US 2025/0201618 A1
(43) Pub. Date: Jun. 19, 2025

(54) DICING/DIE-BONDING FILM AND SEMICONDUCTOR DEVICE MANUFACTURING METHOD

(71) Applicant: Resonac Corporation, Minato-ku, Tokyo (JP)

(72) Inventors: Tsuyoshi TAZAWA, Minato-ku, Tokyo (JP); Naohiro KIMURA, Minato-ku, Tokyo (JP); Kazuhiro YAMAMOTO, Minato-ku, Tokyo (JP); Yukihiro IWANAGA, Minato-ku, Tokyo (JP)

(21) Appl. No.: 18/836,354

(22) PCT Filed: Feb. 14, 2023
(86) PCT No.: PCT/JP2023/005056

§ 371 Date: Aug. 7, 2024

(30) Foreign Application Priority Data
Feb. 17, 2022 (WO) PCT/JP2022/006459

(51) Int. Cl. H01L 21/683; H10D 89/00

(52) U.S. Cl. CPC H01L 21/6836; H10D 89/011; H01L 2221/68327; H01L 2221/68386

(57) ABSTRACT

A dicing die-bonding film including a die-bonding film and a dicing film having a pressure-sensitive adhesive layer laminated on the die-bonding film. The thickness of the die-bonding film is 10 μm or less. The thickness of the pressure-sensitive adhesive layer is less than 10 μm. The dicing film may further have a base material film, and the pressure-sensitive adhesive layer may be provided on the base material film.

### TECHNICAL FIELD

The present disclosure relates to a dicing die-bonding film and a method for producing a semiconductor device using the dicing die-bonding film.

### BACKGROUND ART

During a step of dividing a semiconductor wafer by dicing, a dicing die-bonding film (tape for semiconductor processing) in which a dicing film utilized to fix a semiconductor wafer and a die-bonding film used for bonding adhesion between chips or between a chip and a substrate are integrated, may be used for the production of a semiconductor device (for example, Patent Literatures 1 and 2). The die-bonding film constituting the dicing die-bonding film generally has a thickness of about several dozen μm in many cases.

### CITATION LIST

### Patent Literature

### Patent Literature 1: Japanese Patent No. 6535117

### Patent Literature 2: Japanese Patent No. 6928852

### SUMMARY OF INVENTION

### Technical Problem

Along with the increase in the number of stacked chips and thinning of chips in a semiconductor package, it is desirable to apply a very thin die-bonding film having a thickness of 10 μm or less. However, it has been revealed that when the die-bonding film becomes thin to a thickness of 10 μm or less, it may be difficult for the die-bonding film to be separated in a step of dividing a semiconductor wafer by a method including stretching the dicing die-bonding film. In a case where the die-bonding film is not easily separated, it becomes difficult to pick up chips to which singularized die-bonding film is attached, and this may lead to a decrease in the yield of semiconductor production.

An aspect of the present disclosure relates to a dicing die-bonding film having a die-bonding film with a thickness of 10 μm or less, so as to improve separability of the die-bonding film in a step of dividing a semiconductor wafer by a method including stretching a dicing die-bonding film.

### Solution to Problem

An aspect of the present disclosure relates to a dicing die-bonding film including a die-bonding film and a dicing film having a pressure-sensitive adhesive layer laminated on the die-bonding film. The die-bonding film has a thickness of 10 μm or less, and the pressure-sensitive adhesive layer has a thickness of less than 10 μm.

Another aspect of the present disclosure relates to a method for producing a semiconductor device, the method including: sticking the die-bonding film of the dicing die-bonding film to a semiconductor wafer; and dividing the semiconductor wafer and the die-bonding film by a method including stretching the dicing die-bonding film to thereby form a die-bonding film-attached chip having a chip and the die-bonding film that has been singularized, on the pressure-sensitive adhesive layer.

The present disclosure includes the following:

[1] A dicing die-bonding film including:
a die-bonding film; and
a dicing film including a pressure-sensitive adhesive layer laminated on the die-bonding film,
in which the die-bonding film has a thickness of 10 μm or less, and
the pressure-sensitive adhesive layer has a thickness of less than 10 μm.

[2] The dicing die-bonding film according to [1], in which a 30° peel strength of the pressure-sensitive adhesive layer against the die-bonding film is 6.0 N/25 mm or greater.

[3] The dicing die-bonding film according to [1] or [2], in which the dicing film further includes a base material film, and the pressure-sensitive adhesive layer is provided on the base material film.

[4] A method for producing a semiconductor device, the method including:
sticking the die-bonding film of the dicing die-bonding film according to any one of [1] to [3] to a semiconductor wafer; and
dividing the semiconductor wafer and the die-bonding film by a method including stretching the dicing die-bonding film, and thereby forming die-bonding film-attached chips each including a chip and the die-bonding film that has been singularized, on the pressure-sensitive adhesive layer.

[5] The method according to [4], in which the method of dividing the semiconductor wafer and the die-bonding film is a stealth dicing method.

### Advantageous Effects of Invention

In regard to a dicing die-bonding film having a die-bonding film with a thickness of 10 μm or less, it is possible to improve the separability of the die-bonding film in a step of dividing a semiconductor wafer by a method including stretching the dicing die-bonding film.

### BRIEF DESCRIPTION OF DRAWINGS

FIG. 1 is a plan view and a cross-sectional view illustrating an example of a dicing die-bonding film.

FIG. 2 is a process diagram illustrating an example of a method for producing a semiconductor device.

FIG. 3 is a process diagram illustrating an example of a method for producing a semiconductor device.

### DESCRIPTION OF EMBODIMENTS

The present invention is not intended to be limited to the examples that will be described below. In the following description, each constituent element (also including a step and the like) is not essential unless particularly stated otherwise. The sizes of the constituent elements in each drawing are conceptual, and the relative size relationships between the constituent elements are not limited to those shown in each drawing. Numerical values and ranges thereof in the present disclosure are not intended to limit the present invention. A numerical value range expressed using the term “to” in the present specification indicates a range including the numerical values described before and after the term “to” as the minimum value and the maximum value, respectively. With regard to numerical value ranges described stepwise in the present specification, the upper limit value or lower limit value described for one numerical value range may be replaced with the upper limit value or lower limit value of another numerical value range described stepwise. With regard to a numerical value range described in the present specification, the upper limit value or lower limit value of the numerical value range may be replaced with a value shown in the Examples.

In the present specification, the term (meth)acrylate means acrylate or methacrylate corresponding thereto. This also applies to other similar expressions such as a (meth)acryloyl group and a (meth)acrylic copolymer. Regarding each component and material mentioned as an example in the present specification, unless particularly stated otherwise, one kind thereof may be used alone, or two or more kinds thereof may be used in combination.

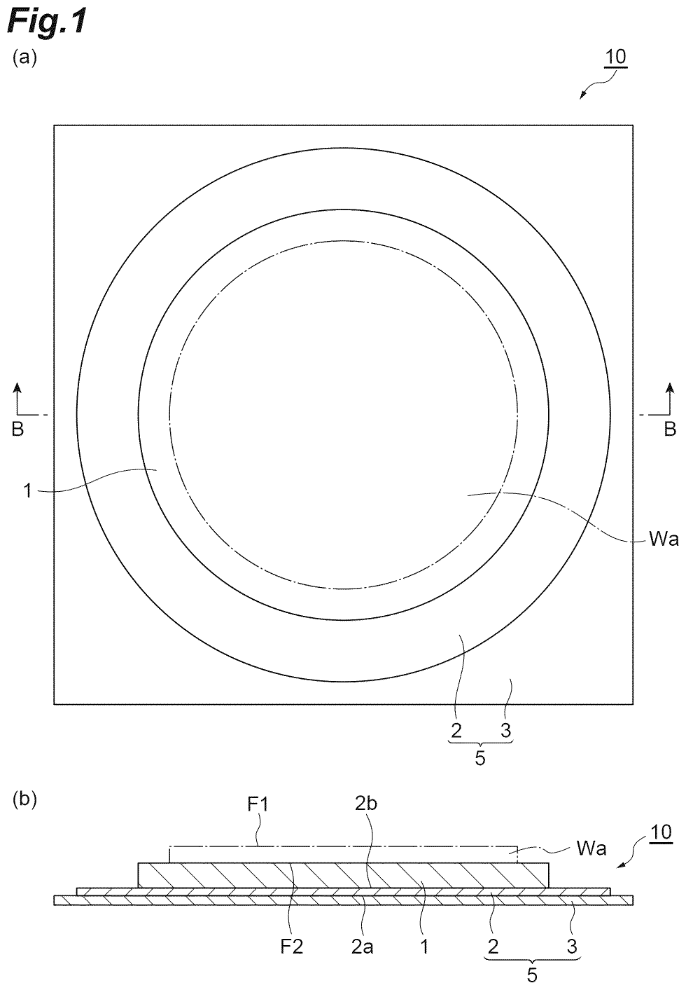

(a) in FIG. 1 is a plan view illustrating an example of a dicing die-bonding film, and (b) in FIG. 1 is a cross-sectional view taken along line B-B in (a) in FIG. 1. The dicing die-bonding film 10 shown in FIG. 1 is composed of a die-bonding film 1 and a dicing film 5 having a pressure-sensitive adhesive layer 2 laminated on the die-bonding film 1. The dicing film 5 has a base material film 3, and the pressure-sensitive adhesive layer 2 is provided on the base material film 3. In FIG. 1, a semiconductor wafer Wa to which the die-bonding film 1 is stuck is also shown.

The die-bonding film 1 is an adhesive film for bonding adhesion of a chip to another chip or a substrate and is also referred to as a die-attach film (DAF). The die-bonding film 1 shown in FIG. 1 as an example has a circular principal surface covering the entire principal surface of the semiconductor wafer Wa.

The die-bonding film 1 can have a thickness of 10 μm or less. When the die-bonding film 1 has a thickness of 10 μm or less, for example, it is advantageous for the production of a thin semiconductor package having a multilayer chip. The thickness of the die-bonding film 1 may be 9 μm or less, 8 μm or less, or 7 μm or less, and may be 1 μm or greater, 2 μm or greater, 3 μm or greater, 4 μm or greater, or 5 μm or greater. The thickness of the die-bonding film 1 may be 1 μm or greater and 10 μm or less, 9 μm or less, 8 μm or less, or 7 μm or less, may be 2 μm or greater and 10 μm or less, 9 μm or less, 8 μm or less, or 7 μm or less, may be 3 μm or greater and 10 μm or less, 9 μm or less, 8 μm or less, or 7 μm or less, may be 4 μm or greater and 10 μm or less, 9 μm or less, 8 μm or less, or 7 μm or less, or may be 5 μm or greater and 10 μm or less, 9 μm or less, 8 μm or less, or 7 μm or less.

The die-bonding film 1 can be a film formed from an adhesive that is conventionally used for bonding of chips. The die-bonding film 1 may be a thermosetting adhesive. The thermosetting adhesive constituting the die-bonding film 1 includes, for example, a high molecular weight resin component and a thermosetting component.

The high molecular weight resin component that may be included in the die-bonding film 1 may include, for example, at least one resin selected from the group consisting of acrylic rubber, polyimide, and a phenoxy resin. The high molecular weight resin component may have a reactive group such as an epoxy group. The weight average molecular weight (standard polystyrene-equivalent value determined by a GPC method) of the high molecular weight resin component may be 100000 to 3000000. The content of the high molecular weight resin component may be 30 to 80 parts by mass with respect to 100 parts by mass of the total mass of the die-bonding film 1.

The thermosetting component that can be included in the die-bonding film 1 is a compound having a reactive group that forms a crosslinked structure by self-polymerization and/or a reaction with a curing agent. The thermosetting component may include, for example, at least one selected from the group consisting of an epoxy resin, a bismaleimide resin, a triazine resin, and a phenol resin. The content of the thermosetting component may be 1 to 30 parts by mass with respect to 100 parts by mass of the amount of the die-bonding film 1.

The thermosetting adhesive constituting the die-bonding film 1 may include other components as necessary. Examples of the other components include a curing agent reacting with the thermosetting component, a curing accelerator accelerating the reaction between the thermosetting component and a curing agent, a coupling agent (for example, a silane coupling agent), and a filler (for example, silica).

The dicing film 5 has a base material film 3 having a rectangular-shaped principal surface and a pressure-sensitive adhesive layer 2 provided on the base material film 3. The pressure-sensitive adhesive layer 2 has a principal surface 2a in contact with the base material film 3, and a principal surface 2b in contact with the die-bonding film 1. The principal surfaces 2a and 2b of the pressure-sensitive adhesive layer 2 can be circular-shaped surfaces having a size sufficient for covering the entire principal surface of the die-bonding film 1.

The pressure-sensitive adhesive layer 2 may have a thickness of less than 10 μm. When the thickness of the pressure-sensitive adhesive layer 2 is less than 10 μm, the die-bonding film 1 having a thickness of 10 μm or less is separated particularly easily in a step of dividing the semiconductor wafer Wa by a method including stretching the dicing die-bonding film 10. Generally, when the pressure-sensitive adhesive layer is thin, the adhesive power tends to decrease, and therefore, it is expected that a thin pressure-sensitive adhesive layer is disadvantageous for the preservation of chips. However, according to the knowledge of the present inventors, in a case where the thickness of the die-bonding film 1 is 10 μm or less, even when the thickness of the pressure-sensitive adhesive layer 2 is less than 10 μm, scattering of chips formed by dividing the semiconductor wafer Wa is sufficiently suppressed. From a similar viewpoint, the thickness of the pressure-sensitive adhesive layer 2 may be 9 μm or less, 8 μm or less, 7 μm or less, 6 μm or less, 5 μm or less, 4 μm or less, or 3 μm or less. The thickness of the pressure-sensitive adhesive layer 2 may be 0.5 μm or greater, 1 μm or greater, or 2 μm or greater. The thickness of the pressure-sensitive adhesive layer 2 may be 0.5 μm or greater and less than 10 μm, 9 μm or less, 8 μm or less, 7 μm or less, 6 μm or less, 5 μm or less, 4 μm or less, or 3 μm or less, may be 1 μm or greater and less than 10 μm, 9 μm or less, 8 μm or less, 7 μm or less, 6 μm or less, 5 μm or less, 4 μm or less, or 3 μm or less, or may be 2 μm or greater and less than 10 μm, 9 μm or less, 8 μm or less, 7 μm or less, 6 μm or less, 5 μm or less, 4 μm or less, or 3 μm or less.

The pressure-sensitive adhesive layer 2 can be a layer formed using an adhesive that is conventionally used for dicing films. The adhesive constituting the pressure-sensitive adhesive layer 2 may be a pressure-sensitive type adhesive or an ultraviolet-curable type pressure-sensitive adhesive. An ultraviolet-curable type pressure-sensitive adhesive is an adhesive having a property that adhesiveness is reduced by ultraviolet irradiation. When an ultraviolet-curable type pressure-sensitive adhesive is used, the adhesive power of the pressure-sensitive adhesive layer 2 can be reduced when irradiated with ultraviolet radiation, for example, before chips having the die-bonding film attached thereto are picked up.

The ultraviolet-curable type adhesive may include, for example, an acrylic resin having a (meth)acryloyl group. The acrylic resin may have a hydroxyl group. The acrylic resin is a polymer including a (meth)acryloyl acid ester as a monomer unit. The ultraviolet-curable type adhesive may further include other components such as a photopolymerization initiator and a crosslinking agent (for example, a polyisocyanate compound) as necessary. The crosslinking agent is a compound having a reactive group that reacts with an acrylic resin, and examples thereof include a polyisocyanate compound.

High peel strength of the pressure-sensitive adhesive layer 2 against the die-bonding film 1 contributes to the suppression of scattering of chips and the suppression of peeling of the die-bonding film 1 from the pressure-sensitive adhesive layer 2 in the step of forming a chip by dividing the semiconductor wafer Wa. From a relevant viewpoint, for example, the 30° peel strength of the pressure-sensitive adhesive layer 2 against the die-bonding film 1 may be 6.0 N/25 mm or greater. The 30° peel strength is a peel strength determined from the stress occurring when the pressure-sensitive adhesive layer 2 is peeled off toward a direction of 30° against the principal surface of the die-bonding film 1. The details of a method for measuring the 30° peel strength will be described in the Examples that will be described below. In a case where the pressure-sensitive adhesive layer 2 is formed using an ultraviolet-curable type adhesive, the 30° peel strength exhibited by the pressure-sensitive adhesive layer 2 against the die-bonding film 1 before ultraviolet irradiation may be 6.0 N/25 mm or greater. The 30° peel strength (30° peel strength before ultraviolet irradiation) of the pressure-sensitive adhesive layer 2 against the die-bonding film 1 may be 20 N/25 mm or less, 17.5 N/25 mm or less, or 15 N/25 mm or less.

The 30° peel strength exhibited by the pressure-sensitive adhesive layer 2 before ultraviolet irradiation against to the die-bonding film 1 may be 6.0 N/25 mm or greater, and the 30° peel strength exhibited by the pressure-sensitive adhesive layer 2 after being irradiated with ultraviolet radiation at a dose of 150 N/cm² against the die-bonding film 1 may be 1.5 N/25 mm or less. When the 30° peel strength of the pressure-sensitive adhesive layer 2 is reduced by ultraviolet irradiation in this way, it is particularly advantageous because scattering of chips and peeling of the die-bonding film 1 from the pressure-sensitive adhesive layer 2 are suppressed, and at the same time, chips are easily picked up. The 30° peel strength as used herein can be a value measured in an environment at a temperature of 23° C. and a relative humidity of 40%.

The base material film 3 constituting the dicing film 5 can be selected from the base material films constituting dicing die-bonding films that are conventionally used in a step of dividing a semiconductor wafer by a method including stretching the dicing die-bonding film. The base material film 3 may be a resin film and may be, for example, a resin film including a resin selected from polyesters (polyethylene terephthalate (PET), polybutylene terephthalate, polyethylene naphthalate, and the like), polyolefins (polyethylene film, polypropylene, and the like), polycarbonate, polyamide, polyimide, polyamideimide, polyetherimide, polyether sulfide, polyether sulfone, polyether ketone, polyphenylene ether, and polyphenylene sulfide. The base material film 3 may be a single-layer film or may be a multilayer film composed of two or more kinds of films. The thickness of the base material film 3 may be, for example, 10 μm or greater, 15 μm or greater, or 20 μm or greater, and may be 200 μm or less, 175 μm or less, or 150 μm or less.

The base material film 3 described as an example in FIG. 1 has a rectangular-shaped principal surface; however, the shape of the base material film 3 is not limited to this. The base material film 3 may be a long film. A plurality of pressure-sensitive adhesive layers 2 may be disposed on one sheet of a long base material film 3.

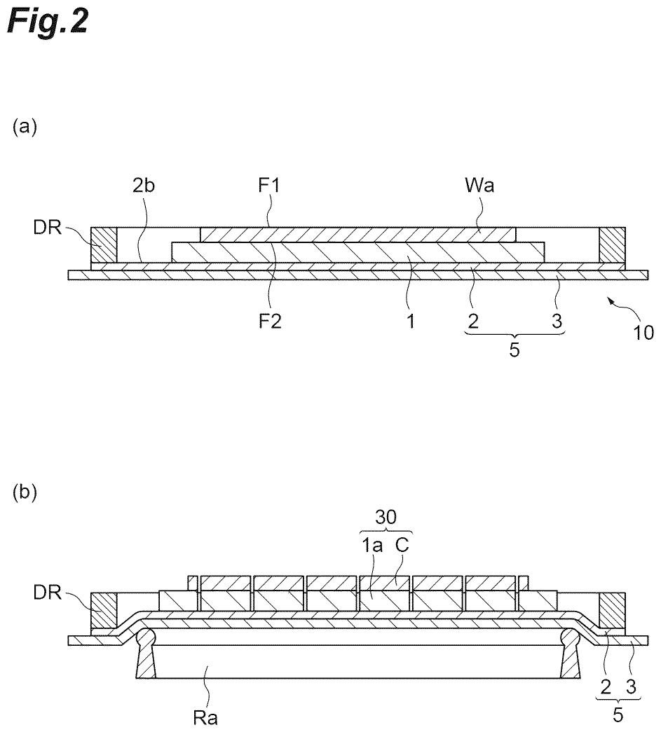

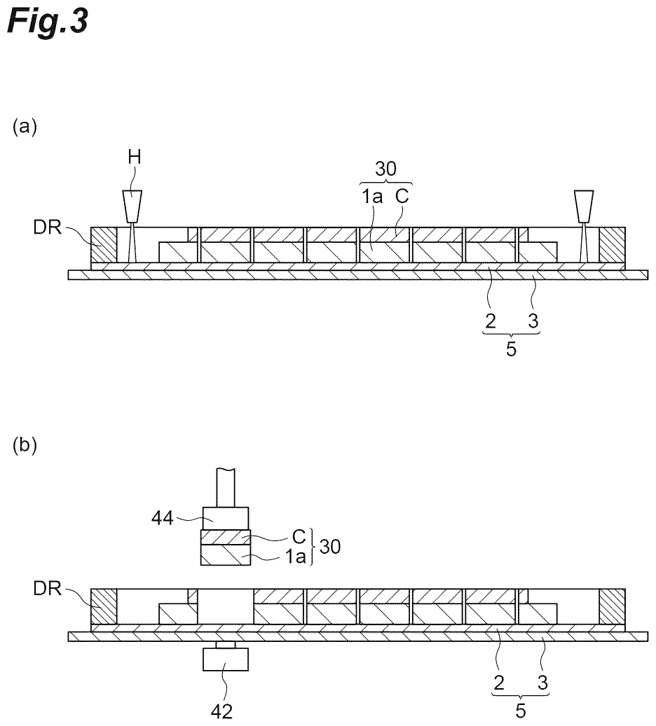

FIG. 2 and FIG. 3 are process diagrams illustrating an example of a method for producing a semiconductor device using the dicing die-bonding film mentioned above as an example. The method described in FIG. 2 and FIG. 3 includes: sticking a die-bonding film 1 of a dicing die-bonding film 10 to a semiconductor wafer Wa; dividing the semiconductor wafer Wa and the die-bonding film 1 by a method including stretching the dicing die-bonding film 10 to thereby form a plurality of die-bonding film-attached chips 30 each having a chip C and a singularized die-bonding film 1a on a pressure-sensitive adhesive layer 2; shrinking the dicing film 5 by heating; and picking up the die-bonding film-attached chips 30.

The semiconductor wafer Wa has two principal surfaces F1 and F2. For example, the principal surface F1 may be a circuit surface, and the principal surface F2 may be a back surface on the opposite side of the circuit surface. The semiconductor wafer Wa may be a silicon wafer. In a case where the semiconductor wafer Wa is divided by a stealth dicing method, before the die-bonding film 1 is stuck, a modified layer may be formed along scheduled cutting lines by irradiating the semiconductor wafer Wa with laser light. Thereafter, the semiconductor wafer Wa may be subjected to back grinding and polishing treatment.

In the case of the example of (a) in FIG. 2, the die-bonding film 1 is stuck to the semiconductor wafer Wa in a direction in which the die-bonding film 1 comes into contact with the principal surface F2 of the semiconductor wafer Wa. Furthermore, a dicing ring DR is stuck to the principal surface 2b on the die-bonding film 1 side of the pressure-sensitive adhesive layer 2 so as to surround the semiconductor wafer Wa.

Thereafter, as shown in (b) in FIG. 2, the dicing film 5 is stretched by pushing up the area of the dicing film 5 inside the dicing ring DR with a ring Ra under low-temperature conditions. The temperature at this time may be, for example, −15 to 0° C. In the case of the stealth dicing method, the semiconductor wafer Wa and the die-bonding film 1 are separated along the modified layer within the semiconductor wafer Wa by stretching the dicing film 5. By this separation, the semiconductor wafer Wa is divided into a plurality of chips C, and the die-bonding film 1 is divided into singularized portions 1a to be attached to individual chips C. That is, die-bonding film-attached chips 30 each having a chip C and a singularized die-bonding film 1a are formed on the pressure-sensitive adhesive layer 2.

After the ring Ra is lowered, as shown in (a) in FIG. 3, a region in the dicing film 5 between the dicing ring DR and the die-bonding film-attached chip 30 is heated by a heater H. The distance between the die-bonding film-attached chips 30 can be further widened by shrinking the dicing film 5 in the heated portions.

After the adhesive force of the pressure-sensitive adhesive layer 2 is reduced by ultraviolet irradiation as necessary, as shown in (b) in FIG. 3, the individual die-bonding film-attached chips 30 pushed up by a push-up tool 42 are picked up using a suction collet 44. A picked up die-bonding film-attached chip 30 may be pressure-bonded to a circuit board or another chip.

The dicing die-bonding film according to the present disclosure is particularly useful for producing a semiconductor device by a method including dividing a thin semiconductor wafer that is susceptible to breakage and a die-bonding film. The thickness of the semiconductor wafer to be divided and the singularized chip may be, for example, 50 μm or less or may be 10 μm or greater.

The dicing die-bonding film according to the present disclosure is also useful for producing a semiconductor device by a method including forming a chip having a rectangular principal surface by dividing a semiconductor wafer. The ratio of the long side with respect to the length of the short side in the principal surface of the chip to be formed may be 3 or more or may be 10 or less. The thickness of the chip having a rectangular-shaped principal surface may be 50 μm or less. By stacking a plurality of thin chips having a rectangular-shaped principal surface, for example, a 3D NAND flash memory can be produced.

### EXAMPLES

The present invention is not limited to the following Examples. Unless particularly stated otherwise, the materials used were all obtained as reagents.

### Example 1

### 1. Synthesis of Acrylic Resin

The following components were introduced into a flask having a capacity of 2000 ml and equipped with a three-one motor, stirring blades, and a nitrogen inlet tube, and a reaction liquid was formed.
Ethyl acetate (solvent): 635 g
2-Ethylhexyl acrylate: 395 g
2-Hydroxyethyl acrylate: 100 g
Methacrylic acid: 5 g
Azobisisobutyronitrile: 0.2 g

The reaction liquid was stirred until the reaction liquid became sufficiently uniform, and then dissolved oxygen in the system was removed by bubbling with nitrogen gas at a flow rate of 500 mL/min for 60 minutes. The temperature of the reaction liquid was raised to 78° C. over 1 hour, and a polymerization reaction was allowed to proceed at the same temperature for 6 hours. Next, the reaction liquid was transferred into an autoclave having a capacity of 2000 mL and equipped with a three-one motor, stirring blades, and a nitrogen inlet tube. The reaction liquid was heated inside a pressurized oven to 120° C. for 4.5 hours in an atmosphere at a pressure of 0.28 MPa. Thereafter, the reaction liquid including a produced polymer was cooled to room temperature (25° C.; hereinafter, the same).

490 g of ethyl acetate was added to the reaction liquid, and the reaction liquid was stirred. Next, 0.025 g of methoquinone (polymerization inhibitor) and 0.10 g of dioctyltin dilaurate (urethanization catalyst) were added thereto. 81 g of 2-methacryloyloxyethyl isocyanate (manufactured by Resonac Corporation, KARENZ MOI (trade name)) was further added to the reaction liquid, and the reaction liquid was heated at 70° C. for 6 hours to allow a reaction between the polymer and 2-methacryloyloxyethyl isocyanate to proceed. The reaction liquid was cooled to room temperature, subsequently ethyl acetate was added thereto, and an acrylic resin solution including an acrylic resin having a methacryloyloxy group and a hydroxyl group at a concentration of 35% by mass was obtained.

The obtained acrylic resin solution was vacuum dried overnight at 60° C., and a remaining solid content was subjected to elemental analysis in a fully automated elemental analysis apparatus (manufactured by Elementar Analysensysteme GmbH, trade name: vario EL). From the nitrogen content obtained from the elemental analysis, the amount of 2-methacryloyloxyethyl group introduced per 1 g of the acrylic resin was calculated, and the amount was 0.89 mmol/g.

The weight average molecular weight (standard polystyrene-equivalent value) of the acrylic resin was determined by GPC measurement of the acrylic resin. For the GPC measurement, SD-8022/DP-8020/RI-8020 manufactured by Tosoh Corporation was used. As the column, Gelpack GL-A150-S/GL-A160-S of Resonac Corporation was used. Tetrahydrofuran was used as the eluent. The weight average molecular weight of the acrylic resin was 350000.

### 2. Dicing Film

A varnish (concentration of components other than solvent: 25% by mass) for forming an ultraviolet-curable type pressure-sensitive adhesive layer was prepared by mixing the following components. The acrylic resin was synthesized in the section “1. Synthesis of acrylic resin”. The term “solid content” means the quantity of components other than the solvent.
Acrylic resin: 100 parts by mass (solid content)
Photopolymerization initiator (1-hydroxycyclohexyl phenyl ketone, manufactured by Ciba Specialty Chemicals Co., Ltd., IRGACURE 184, “IRGACURE” is a registered trademark): 2.0 parts by mass
Crosslinking agent (polyfunctional isocyanate, manufactured by Nippon Polyurethane Industry Co., Ltd., CORONATE L, solid content 75%): 4.1 parts by mass (solid content)
Ethyl acetate (solvent)

A polyethylene terephthalate film (width 450 mm, length 500 mm, thickness 38 μm) having a release surface was prepared as a cover film. The varnish was applied on the release surface of the cover film using an applicator, and the coating film was dried at 80° C. for 5 minutes. As a result, a laminated film composed of the cover film and an pressure-sensitive adhesive layer (thickness 2 μm) formed thereon was obtained.

A polyolefin film (width 450 mm, length 500 mm, thickness 100 μm) having a corona-treated surface was prepared as a base material film. In the following description, the longitudinal direction of the base material film will be referred to as MD direction, and a direction perpendicular to the MD direction will be referred to as TD direction. This base material film was laminated on the pressure-sensitive adhesive layer of the above-described laminated film at room temperature, in a direction in which the corona-treated surface was in contact with the pressure-sensitive adhesive layer. Next, the entirety was pressed with a rubber roll to closely adhere the base material film to the pressure-sensitive adhesive layer. A dicing film having the base material film, the pressure-sensitive adhesive layer, and the cover film was left to stand at room temperature for 3 days.

### 3. Die-Bonding Film

A mixture including the following components and cyclohexanone was stirred and then kneaded for 90 minutes using a bead mill.
Epoxy resin (N500P-10 (trade name), DIC Corporation, cresol novolac type epoxy resin, epoxy equivalent 200, molecular weight 980, softening point 85° C.): 55 parts by mass
Phenol resin (MEH-7800M (trade name), manufactured by Meiwa Plastic Industries, Ltd., hydroxyl group equivalent 175): 45 parts by mass
Silane coupling agent 1 (NUC A-189 (trade name), manufactured by Nippon Unicar Company Limited, γ-mercaptopropyltrimethoxysilane): 1.7 parts by mass
Silane coupling agent 2 (NUC A-1160 (trade name), manufactured by Nippon Unicar Company Limited, γ-ureidopropyltriethoxysilane): 0.2 parts by mass
Filler (AEROSIL R972 (trade name), manufactured by NIPPON AEROSIL CO., LTD., silica, average particle size 0.016 μm): 32 parts by mass

“AEROSIL R972” is silica particles having an organic group (for example, methyl group) on the surface.

The following components were added to the mixture after kneading, and the mixture was further stirred. Thereafter, a varnish for forming a die-bonding film was obtained by performing vacuum degassing.
Acrylic rubber having an epoxy group (HTR-860P-3 (trade name), manufactured by Nagase ChemteX Corporation, content of glycidyl acrylate or glycidyl methacrylate: 3% by mass, weight average molecular weight: 800000): 280 parts by mass
Curing accelerator (CUREZOL 2PZ-CN (trade name), “CUREZOL” is a registered tradename, manufactured by SHIKOKU CHEMICALS CORPORATION, 1-cyanoethyl-2-phenylimidazole): 0.5 parts by mass

A polyethylene terephthalate film (thickness 35 μm) having a release surface was prepared as a carrier film. The varnish for forming a die-bonding film was applied on the release surface of the carrier film, and the coating film was heated and dried at 140° C. for 5 minutes. As a result, a laminated film composed of the carrier film and a die-bonding film (adhesive layer having a thickness of 7 μm) in a stage-B state formed on the carrier film was obtained.

### 4. Production of Dicing Die-Bonding Film

The laminated film having the die-bonding film was cut into a circular shape (diameter: 312 mm). The dicing film from which the cover film had been peeled off was stuck to the circular-shaped die-bonding film in a direction in which the pressure-sensitive adhesive layer was in contact with the die-bonding film. The laminated body thus formed was left to stand at room temperature for 1 day. Thereafter, the outer side of the portion of the dicing film laminated on the die-bonding film was cut, and a dicing die-bonding film having a circular-shaped die-bonding film and a circular-shaped (diameter: 370 mm) dicing film that covered the die-bonding film and had a portion protruding from the die-bonding film, was obtained. A plurality of dicing die-bonding films to be provided for the above-mentioned various evaluation tests were produced by similar operations.

### Examples 2 to 5 and Comparative Examples 1 to 5

A plurality of dicing die-bonding films were produced in the same manner as in Example 1, except that the thicknesses of the die-bonding film and the pressure-sensitive adhesive layer were changed as shown in Table 1 or Table 2.

### Reference Examples 1 to 3

A plurality of dicing die-bonding films were produced in the same manner as in Example 1, except that the thickness of the die-bonding film was changed to 20 μm, and the thickness of the pressure-sensitive adhesive layer was changed as indicated in Table 1.

### 5. Evaluation

### (1) Adhesive Power (30° Peel Strength) of Pressure-Sensitive Adhesive Layer Against Die-Bonding Film

From each of the dicing die-bonding films, a measurement sample (laminated body composed of a pressure-sensitive adhesive layer and an adhesive layer (die-bonding film)) having a size of 25 mm in width and 100 mm in length was cut out. Each measurement sample was irradiated with ultraviolet radiation (UV) under the conditions of an illuminance of 100 mW/cm² and an irradiation dose of 150 mJ/cm². For the measurement sample before ultraviolet irradiation and after ultraviolet irradiation, the peel strength (30° peel strength) at the time of tearing off the pressure-sensitive adhesive layer from the die-bonding film at a peeling angle of 30° was measured. The tensile rate was 60 mm/min. The measurement sample was stored in an environment at a temperature of 23° C. and a relative humidity of 40%, and the 30° peel strength was measured in the same environment.

### (2) Processability Evaluation

### (i) Dicing Test

A protective tape was stuck to the front surface of a silicon wafer (diameter: 12 inches, thickness: 775 μm). By irradiating the surface on the protective tape side of the silicon wafer and the surface on the opposite side thereof with laser light under the following conditions for stealth dicing, a modified layer for stealth dicing was formed inside the silicon wafer along scheduled cutting lines composed of a plurality of straight lines orthogonally intersecting each other.

### Conditions for Stealth Dicing:

Stealth dicing apparatus: DFL7361 (manufactured by DISCO Corporation)
Laser oscillator type: semiconductor laser pumped Q-switched solid-state laser
Wavelength: 1342 nm
Frequency: 60 kHz
Power output: 0.8 W
Number of passes: 2
Chip size: 3 mm×12 mm
Dicing speed: 800 mm/second

The surface of the silicon wafer on the opposite side of the protective tape was polished using a grinder/polisher device (DGP8761, manufactured by DISCO Corporation) until the thickness of the silicon wafer reached 30 μm. The polished surface of the silicon wafer was stuck to the die-bonding film of the dicing die-bonding film under the following conditions. In this case, the direction of sticking was adjusted such that the directions of the modified layer of the silicon wafer were along the MD direction and the TD direction of the base material film of the dicing die-bonding film. Furthermore, the pressure-sensitive adhesive layer of the portion protruding from the die-bonding film was stuck to a dicing ring. Thereafter, the protective tape was peeled off from the silicon wafer.

### Conditions for Sticking:

Sticking apparatus: DFM2800 (manufactured by DISCO Corporation)
Sticking temperature: 65° C.
Sticking speed: 10 mm/s
Sticking tension level: level 7

Next, the dicing die-bonding film was stretched by cooling expansion under the following conditions using a die separator (DDS2300, manufactured by DISCO Corporation), and as a result, the silicon wafer and the die-bonding film were divided. Thereafter, the dicing film was shrunk by heating under the following conditions.

### Conditions for Cooling Expansion:

Cooling temperature: 0° C.
Time for cooling: 120 seconds
Upthrust amount: 10 mm
Upthrust speed: 120 mm/second
Retention time after upthrust: 10 seconds

### Heating Conditions:

Heater temperature: 250° C.
Heater rotation speed: 10°/second
Upthrust amount: 8 mm
Waiting time for tape cooling: 10 seconds

After the shrinkage of the dicing film, the pressure-sensitive adhesive layer was irradiated with ultraviolet radiation under the following conditions, and thereby the adhesive power of the pressure-sensitive adhesive layer was reduced.

### Conditions for Ultraviolet Irradiation:

Illuminance of ultraviolet radiation: 100 mW/cm²
Irradiation dose of ultraviolet radiation: 150 mJ/cm²

### (ii) Processability

### Retention Properties

In the course of a dicing test, the presence or absence of a phenomenon of chips scattering, and the presence or absence of peeling between the adhesive layer (die-bonding film) at the portion protruding from the silicon wafer and the pressure-sensitive adhesive layer were checked. The retention properties were evaluated according to the following criteria.

A: No scattering of chips, and no peeling at the interface between the adhesive layer and the pressure-sensitive adhesive layer

B: No scattering of chips but peeling occurred at the interface between the adhesive layer and the pressure-sensitive adhesive layer

C: Scattering of chips occurred

### Separability

The die-bonding films between adjacent chips were all observed, and separability was evaluated according to the following criteria, based on the number of sites where the die-bonding film was not separated.

A: 0

B: 1 or more and less than 10

C: 10 or more

### Kerf Width

The width (kerf width) of lattice-shaped gaps formed between adjacent chips was measured by microscopic observation. The kerf widths of gaps along the MD direction or the TD direction around the chips were measured at two sites in the vicinity of each of four positions that divided the portion corresponding to the outer periphery of the silicon wafer into four equal parts, and one site at the central part of the silicon wafer. The average value of the kerf widths of the gaps along the MD direction or the TD direction measured at a total of 9 sites was determined.

### Pickup Performance

After the evaluation of the retention properties, separability, and kerf width, one hundred die-bonding film-attached chips were picked up under the following conditions.

### Condition for Pickup:

Die-bonder apparatus: DB830-P (manufactured by Fasford Technology Co., Ltd.)
Upthrust pin: EJECTOR NEEDLE SEN2-83-05 (diameter: 0.7 mm, tip shape: hemisphere having a radius of 350 μm, manufactured by Micro-Mechanics Pte., Ltd.)
Upthrust height: 250 μm
Upthrust speed: 1 mm/second
Number of upthrust pins: 8 pins

The pickup performance is evaluated according to the following criteria, based on the pickup success rate.

A: 100%

B: 80% or greater and less than 100%

C: 60% or greater and less than 80%

TABLE 1

| | | Example | | | | |
|---|---|---|---|---|---|---|
| | | 1 | 2 | 3 | 4 | 5 |
| Die-bonding film thickness [μm] | | 7 | 7 | 7 | 5 | 10 |
| Pressure-sensitive adhesive | | 2 | 4 | 8 | 2 | 2 |
| layer thickness [μm] | | | | | | |
| 30° peel | Before | 6.6 | 7.5 | 7.5 | 7.6 | 6.1 |
| strength | ultraviolet | | | | | |
| [N/25 mm] | irradiation | | | | | |
| | After | 0.93 | 0.78 | 0.72 | 1.2 | 0.95 |
| | ultraviolet | | | | | |
| | irradiation | | | | | |
| Retention properties | | A | A | A | A | A |
| Separability | | A | A | A | A | A |
| Kerf width | MD direction | 37.9 | 35.4 | 34.4 | 44 | 43.2 |
| [μm] | TD direction | 61.8 | 56.2 | 52.3 | 79.3 | 67.8 |

| | | | | | |
|---|---|---|---|---|---|
| Pickup performance | A | A | A | A | A |

TABLE 2

| | | | | | | | Reference | | |
|---|---|---|---|---|---|---|---|---|---|
| | | Comparative Example | | | | | Example | | |
| | | 1 | 2 | 3 | 4 | 5 | 1 | 2 | 3 |
| Die-bonding film thickness [μm] | | 7 | 7 | 7 | 10 | 5 | 20 | 20 | 20 |
| Pressure-sensitive adhesive | | 10 | 20 | 30 | 10 | 10 | 2 | 4 | 10 |
| layer thickness [μm] | | | | | | | | | |
| 30° peel | Before | 6.5 | 6.9 | 6.2 | 6.3 | 6.2 | 4.5 | 4.9 | 6.3 |
| strength | ultraviolet | | | | | | | | |
| [N/25 mm] | irradiation | | | | | | | | |
| | After | 0.70 | 0.78 | 0.77 | 0.65 | 0.70 | 1.1 | 0.90 | 0.60 |
| | ultraviolet | | | | | | | | |
| | irradiation | | | | | | | | |
| Retention properties | | A | A | A | A | A | B | B | A |
| Separability | | B | C | C | B | C | A | A | A |
| Kerf width | MD direction | 31 | 31.4 | 29 | 36.3 | 36.1 | 37.2 | 35.7 | 31 |
| [μm] | TD direction | 51.7 | 59.5 | 61.1 | 55.9 | 61.3 | 60.2 | 54.5 | 54.7 |

| | | | | | | | | |
|---|---|---|---|---|---|---|---|---|
| Pickup performance | A | A | A | A | A | A | A | A |

The evaluation results are shown in Table 1. In a case where the thickness of the die-bonding film is 20 μm as in the cases of Reference Examples 1 to 3, when the thickness of the pressure-sensitive adhesive layer becomes thin, there is a tendency that peeling of the die-bonding film is likely to occur in the course of dicing. However, in a case where the thickness of the die-bonding film is 10 μm or less as in the cases of Examples 1 to 5 and Comparative Examples 1 to 5, it was verified that even when the pressure-sensitive adhesive layer becomes thin, satisfactory retention properties are maintained in the course of dicing. Furthermore, it was also verified that when the thickness of the pressure-sensitive adhesive layer is less than 10 μm as in the cases of Examples 1 to 5, separability of the die-bonding film is improved. In addition, it was also verified that when the pressure-sensitive adhesive layer becomes thin, a large kerf width is likely to be ensured.

### REFERENCE SIGNS LIST

1: die-bonding film, 1a: singularized die-bonding film, 2: pressure-sensitive adhesive layer, 3: base material film, 5: dicing film, 10: dicing die-bonding film, 30: die-bonding film-attached chip, C: chip, Wa: semiconductor wafer.

1. A dicing die-bonding film comprising:
a die-bonding film; and
a dicing film comprising a pressure-sensitive adhesive layer laminated on the die-bonding film,
wherein the die-bonding film has a thickness of 10 μm or less, and
the pressure-sensitive adhesive layer has a thickness of less than 10 μm.

2. The dicing die-bonding film according to claim 1, wherein a 30° peel strength of the pressure-sensitive adhesive layer against the die-bonding film is 6.0 N/25 mm or greater.

3. The dicing die-bonding film according to claim 1, wherein the dicing film further comprises a base material film, and the pressure-sensitive adhesive layer is provided on the base material film.

4. A method for producing a semiconductor device, the method comprising:
sticking the die-bonding film of the dicing die-bonding film according to claim 1 to a semiconductor wafer; and
dividing the semiconductor wafer and the die-bonding film by a process including stretching the dicing die-bonding film, and thereby forming die-bonding film-attached chips each comprising a chip and the die-bonding film that has been singularized, on the pressure-sensitive adhesive layer.

5. The method according to claim 4, wherein the process of dividing the semiconductor wafer and the die-bonding film is a stealth dicing process.
